(19) United States
(12) Patent Application Publication
(10) Pub. No.: US 2008/0057612 A1
(43) Pub. Date: Mar. 6, 2008

(54) METHOD FOR ADDING AN IMPLANT AT THE SHALLOW TRENCH ISOLATION CORNER IN A SEMICONDUCTOR SUBSTRATE

(76) Inventors: Hung Q. Doan, Rochester, NY (US); Eric G. Stevens, Webster, NY (US)

Correspondence Address: F-P, Patent Legal Staff;Eastman Kodak Company, 343 State Street, Rochester, NY, 14650-2201, US

(21) Appl. No.: 11/840,299

(22) Filed: Aug. 17, 2007

Related U.S. Application Data
(60) Provisional application No. 60/842,075, filed on Sep. 1, 2006.

(51) Int. Cl. H01L 21/76; H01L 21/00

(52) U.S. Cl. 438/57; 438/421; 257/E21.001; 257/E21.54

(57) ABSTRACT

A method for fabricating corner implants in the shallow trench isolation regions of an image sensor includes the steps of forming a photoresist layer on a first hard mask layer overlying an etch-stop layer on a semiconductor substrate. The photoresist mask is patterned to create an opening and the portion of the first hard mask layer exposed in the opening is etched down to the etch-stop layer. A first dopant is implanted into the semiconductor substrate through the exposed etch-stop layer. The photoresist mask is removed and a second hard mask layer is formed on the remaining structure and etched to create sidewall spacers along the side edges of the first hard mask layer. The etch stop layer and the semiconductor substrate positioned between the sidewall spacers are etched to create a trench and a second dopant implanted into the side and bottom walls of the trench.

### CROSS-REFERENCE TO RELATED APPLICATIONS

Reference is made to and priority claimed from U.S. Provisional Application Ser. No. 60/842,075, filed Sep. 1, 2006 entitled METHOD FOR ADDING AN IMPLANT AT THE SHALLOW TRENCH ISOLATION CORNER.

### TECHNICAL FIELD

The present invention generally relates to a method of fabricating an integrated circuit in a semiconductor device. More particularly, the present invention relates to fabricating an implant at the shallow trench isolation corner of an image sensor to suppress the surface dark current.

### BACKGROUND

Typically metallic or lattice defects, surface states, and lattice stress produce dark current in image sensors. Dark current is an undesirable signal that is generated in a semiconductor substrate and collected by a photodetector. Dark current is generated when light is both striking and not striking the photodetector. Dark current adds noise, which reduces the dynamic range and the signal-to-noise ratio of the image sensor.

Shallow trench isolation physically isolates pixels so that signal collected in any given pixel will not spill over to the neighboring pixel or pixels. Unfortunately, STI features can potentially produce surface dark current because the features create additional surface states and localized high stress regions. Image sensors, such as Complementary Metal Oxide Semiconductor (CMOS) image sensors, with STI regions suffer from high surface dark current at the sidewalls and bottom of the STI trench. Typically, high angle implants are performed on the sides and bottom of the STI regions to reduce the surface dark current. Additionally, corner implants further suppress surface dark current.

FIG. 1 shows a cross-sectional view of a semiconductor substrate with a shallow trench isolation region according to the prior art. Substrate 10 includes a STI having a trench with corner implants 13 and sidewall implants 14. One conventional method for fabricating corner implants 13 requires the formation and patterning of photoresist mask 12 on the device and the implantation of dopants (represented by arrows) into the corners of the shallow trench. Unfortunately, the formation and patterning of photoresist mask 12 creates an additional processing step in the manufacture of semiconductor devices.

Another method to form corner implants 13 is to remove a hard mask (not shown) from the sidewalls and corners of the shallow trench region of the semiconductor substrate and then simultaneously implant both the sidewalls and corners. Unfortunately, subsequent etches performed during the fabrication process can create undesirable silicon pits at the corner implants of the STI.

Therefore, there exists a need in image sensors to reduce the surface dark current in the sidewall implant.

Furthermore, there exists a need to provide a method for forming a shallow trench isolation that is self-aligned.

Additionally, there exists a need for forming corner implants that does not create silicon pits in the STI corner during subsequent processing of the image sensor.

### SUMMARY

The present invention is directed to overcoming one or more of the problems set forth above. The present invention relates to a method for fabricating an image sensor with corner implants in the shallow trench isolation regions. The method includes the steps of forming a first hard mask layer of over an etch-stop layer on a semiconductor substrate and providing a photoresist mask over the hard mask layer. The photoresist mask is patterned to create an opening and the portion of the first hard mask layer exposed in the opening is etched down to the etch-stop layer. A first dopant is then implanted into the semiconductor substrate through the exposed etch-stop layer. The photoresist mask is removed and a second hard mask layer is formed on the remaining structure and etched to create sidewall spacers along the side edges of the first hard mask layer. The etch stop layer and the semiconductor substrate positioned between the sidewall spacers are then etched to create a trench and a second dopant implanted into the side and bottom walls of the trench. The trench is then typically filled with a dielectric material to create a shallow trench isolation region in the semiconductor substrate.

The present advantage has the advantage of reducing the surface dark current by forming corner implants that do not cause silicon pitting with a shallow trench isolation that is self-aligned.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1 shows a cross-sectional view of a semiconductor substrate with a shallow trench isolation region according to the prior art;

FIG. 2 shows a cross-sectional view of a semiconductor substrate and a first hard mask layer in an embodiment in accordance with the invention;

FIG. 3 shows a cross-sectional view of a semiconductor substrate with an etched first hard mask layer in an embodiment in accordance with the invention;

FIG. 4 shows a cross-sectional view of a semiconductor substrate with a shallow implant in an embodiment in accordance with the invention;

FIG. 5 shows a cross-sectional view of a semiconductor substrate with a second hard mask layer in an embodiment in accordance with the invention;

FIG. 6 shows a cross-sectional view of a semiconductor substrate with an etched second hard mask layer in an embodiment in accordance with the invention;

FIG. 7 shows a cross-sectional view of a semiconductor substrate with a shallow trench in an embodiment in accordance with the invention;

FIG. 8 shows a cross-sectional view of a semiconductor substrate with a shallow trench isolation and side wall implants in an embodiment in accordance with the invention;

FIG. 9a shows a first cross-sectional view of a semiconductor substrate containing devices between two shallow trench isolations with sidewall implants in embodiments in accordance with the invention; and

FIG. 9b shows a second cross-sectional view of a semiconductor substrate containing devices between two shallow trench isolations with sidewall implants in embodiments in accordance with the invention.

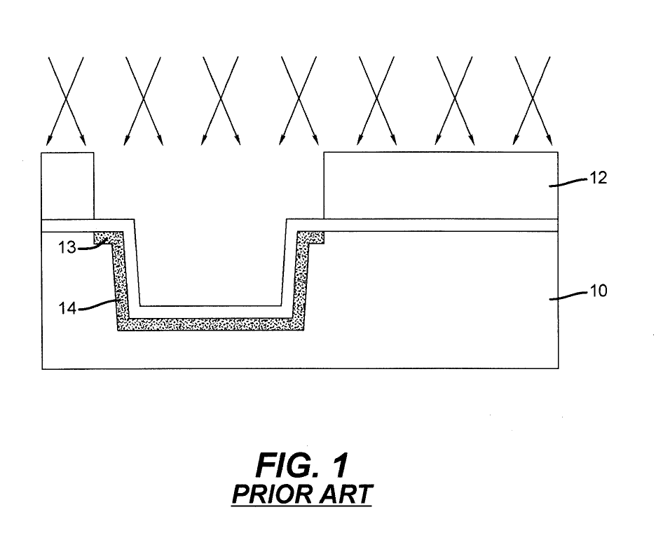

### DETAILED DESCRIPTION

The present invention includes a method for forming corner implants in STI regions of an integrated circuit. The implant is self-aligned to the STI corner without the need for additional photoresist masking or exposing the STI corner, which can lead to silicon pitting. The present invention is described with reference to the accompanying drawings, in which exemplary embodiments of the invention are shown. The invention may, however, be embodied in may different forms and should not be construed as being limited to the embodiments set forth herein; rather, these embodiments are provided to fully convey the concept of the present invention to those skilled in the art. The drawings are not to scale and many portions are exaggerated for clarity.

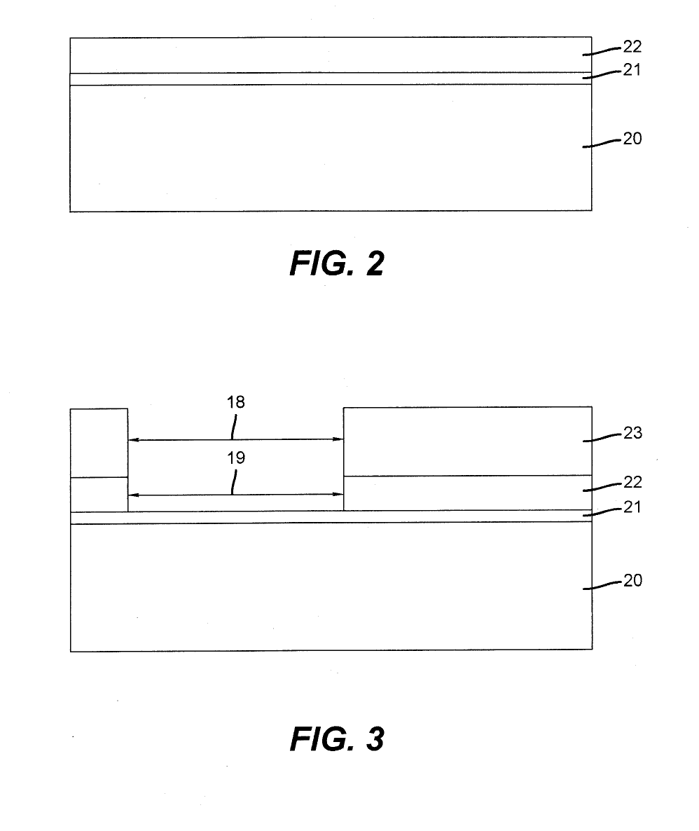

Referring to FIG. 2, a cross-sectional view of a semiconductor substrate and a first hard mask layer in an embodiment in accordance with the invention is shown. Semiconductor substrate 20 is silicon, silicon carbide, silicon-on-insulator, silicon-germanium, gallium-nitride, or gallium-arsenide in one embodiment in accordance with the invention. Furthermore, semiconductor substrate 20 can be n-type, p-type or an undoped substrate. Additionally, semiconductor substrate 20 may optionally have an epitaxial layer (not shown) that is the same or opposite conductivity type as semiconductor substrate 20. Semiconductor substrate 20 may also contain wells that are of the same or opposite conductivity type as either the epitaxial layer or semiconductor substrate 20 implanted therein.

Etch-stop layer 21 is formed on the surface of semiconductor substrate 20. In one embodiment in accordance with the invention, etch-stop layer 21 is formed as a thin layer of silicon dioxide or polysilicon. A silicon dioxide etch-stop layer may be grown on the substrate in oxygen or steam typically at 800-1200° C. Alternatively, etch stop layer 21 may be deposited directly on the surface of semiconductor substrate 20 by oxide chemical vapor deposition. Oxide chemical vapor deposition is accomplished by a low-pressure low temperature deposition or a plasma enhanced chemical vapor deposition.

First hard mask layer 22 is deposited on etch-stop layer 21 via traditional processes such as low pressure chemical vapor deposition (LPCVD) or plasma enhanced chemical vapor deposition (PECVD). First hard mask layer 22 is configured as any mask layer that is deposited or grown on the device. Examples of a hard mask layer include, but are not limited to, silicon nitride, polysilicon and a metal film.

FIG. 3 shows a cross-sectional view of a semiconductor substrate with an etched first hard mask layer in an embodiment in accordance with the invention. Photoresist mask 23 is coated onto first hard mask layer 22 and patterned to form opening 18. An anisotropic etch is then performed to remove the portion of first hard mask layer 22 exposed in opening 18. Opening 19 in first hard mask layer 22 is wider than the width of a shallow trench that will be formed in semiconductor substrate 20.

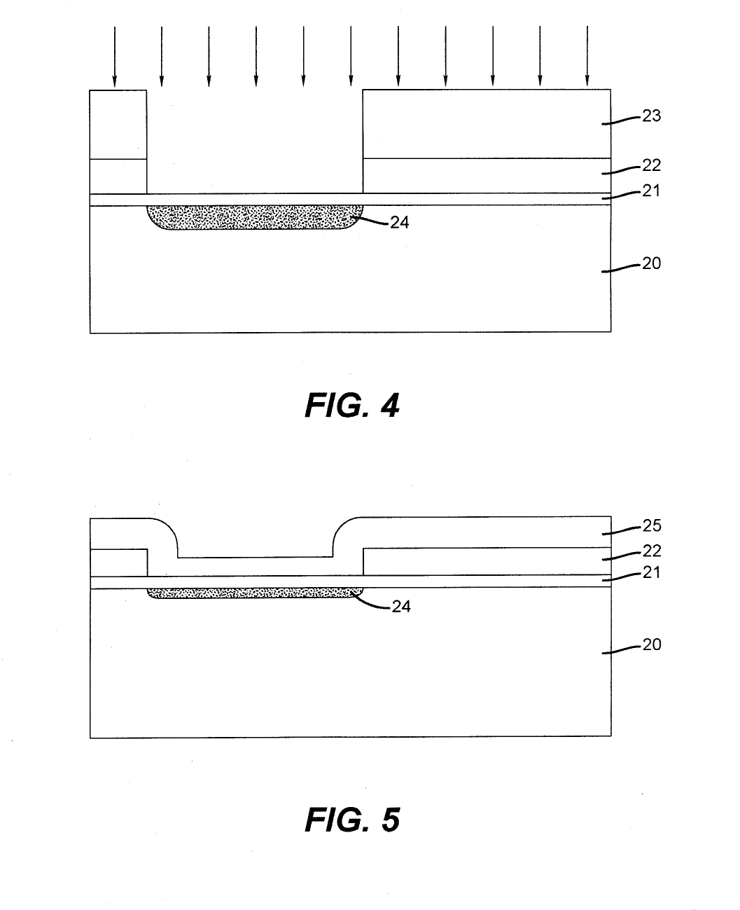

Referring to FIG. 4, a cross-sectional view of a semiconductor substrate with a shallow implant in an embodiment in accordance with the invention is shown. Shallow implant 24 is typically implanted to a depth between 100 and 500 A in an embodiment in accordance with the invention. Photoresist mask 23 and first hard mask layer 22 serve as a protective mask for the regions of the semiconductor substrate in which a shallow implant is not to be formed. Shallow implant 24 is a dopant having a conductivity type opposite the conductivity type of the photodetectors (not shown) in the image sensor. In one embodiment in accordance with the invention, the dopant is an n-type dopant such as phosphorus, arsenic, or antimony. In another embodiment in accordance with the invention, the dopant is a p-type dopant such as boron, aluminum, gallium or indium.

The implant energy depends on the particular dopant used and is typically between 5-200 KeV for an implant depth typically between 100 and 500 A. The implant profile distribution is such that the implant dopant remains near the surface of substrate 20. If thermal processing occurs after implantation the dopant will diffuse away from the initial implant area. This diffusion is accounted for when choosing the initial implant depth and concentration of the elementary dopant.

Photoresist mask 23 is then removed by an oxygen ashing process, wet sulfuric acid mixed with peroxide, or solvent chemistry methods. If adequate thickness is used for first hard mask layer 22, photoresist mask 23 is removed and first hard mask layer 22 is the protective mask for the implant in an embodiment in accordance with the invention. In another embodiment in accordance with the invention, shallow implant 24 is formed in substrate 20 before first hard mask layer 22 is ansiotropically etched.

FIG. 5 shows a cross-sectional view of a semiconductor substrate with a second hard mask layer in an embodiment in accordance with the invention. Second hard mask layer 25 is deposited on first hard mask layer 22 and the exposed portion of etch-stop layer 21. Second hard mask layer 25 may be of the same or different material than first hard mask layer 22. Second hard mask layer 25 is of a material that has a slow removal rate during an STI anisotropic etch when compared to the silicon removal rate in an embodiment in accordance with the invention.

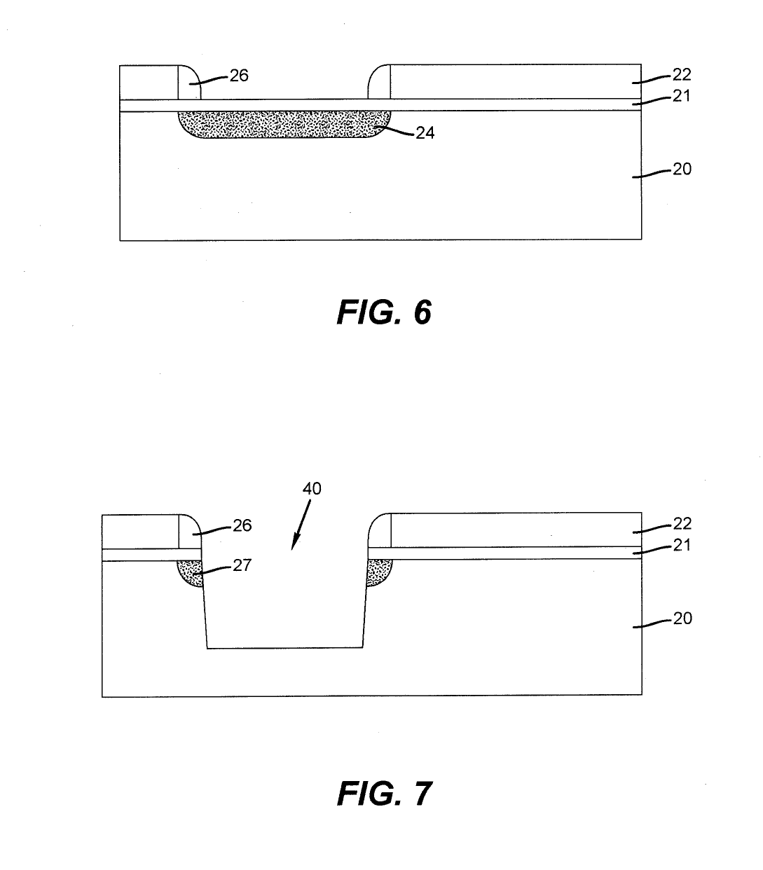

Referring to FIG. 6, a cross-sectional view of a semiconductor substrate with an etched second hard mask layer in an embodiment in accordance with the invention is shown. An anisotropic etch, such as plasma etching, is used to form sidewall spacers 26 along the sides of first hard mask layer 22. Sidewall spacers 26 are positioned over the perimeter portions of shallow implant 24. Sidewall spacers 26 each typically have a width between 0.05 and 0.2 μm in an embodiment in accordance with the invention. The width of sidewall spacers 26 is primarily controlled by the thickness of second hard mask layer 25 (see FIG. 5).

FIG. 7 shows a cross-sectional view of a semiconductor substrate with a shallow trench in an embodiment in accordance with the invention. Shallow trench 40 is formed by anisotropically etching through shallow implant 24 and into semiconductor substrate 20. Shallow trench 40 is formed in the area between sidewall spacers 26 in semiconductor substrate 20. Corner implants 27 are the only portions of shallow implant 24 to remain in substrate 20. By etching through opening 19 in second hard mask layer 25, the inside edges of corner implants 27 are self-aligned with the inside edge of second hard mask layer 25.

In one embodiment in accordance with the invention, shallow trench 40 typically has a depth between 0.3 and 0.5 μm and a width between 0.15 and 0.6 μm. The width of shallow trench 40 should be as small as possible to minimize the amount of semiconductor substrate used for the STI regions. Minimizing the size of the STI regions advantageously increases the amount of substrate that is available for photodetectors in an image sensor.

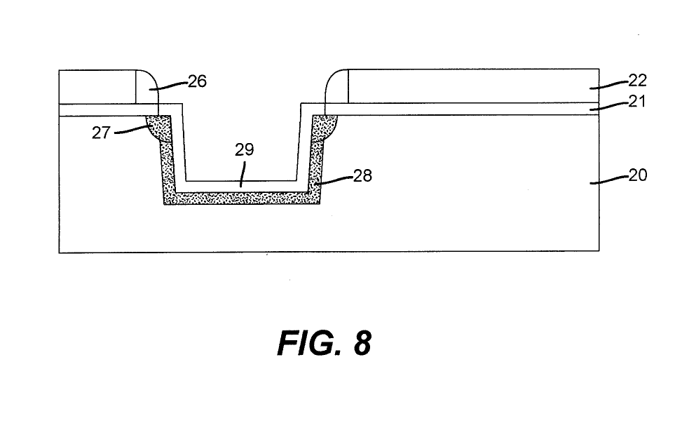

Referring to FIG. 8, the sidewalls and bottom of shallow trench 40 are implanted with implant dopant 28. Implant dopant 28 is typically implanted between 0 and 100 A from the exposed surface of the substrate 20 and the concentration of implant dopant 28 is typically between 10¹²-10¹³ atoms/cm² in an embodiment in accordance with the invention. This implant is usually done at an angle and quaded (i.e., done at four separate wafer rotations ninety degrees apart) so that implant dopant 28 is implanted into all four sides and the bottom of shallow trench 40.

Implant dopant 28 is of the same conductivity type as the corner implants 27. In one embodiment in accordance with the invention, implant dopant 28 is also the same dopant as the shallow implant 24 dopant. Implant dopant 28 can be an n-type dopant such as phosphorus, arsenic, or antimony, or a p-type dopant such as boron, aluminum, gallium or indium.

Dielectric layer 29 is typically formed on the regions of the silicon implanted with dopant 28 by a low-pressure chemical vapor deposition, an atmospheric pressure chemical vapor deposition, a plasma enhanced chemical vapor deposition, or a high density plasma deposition. Examples of a dielectric material that can be used for dielectric layer 29 include, but are not limited to, a liner oxide or nitride. Dielectric layer 29 can be grown or deposited either prior to or after the implantation of implant dopant 28. Isolation trench 40 is then filled with a dielectric material (not shown).

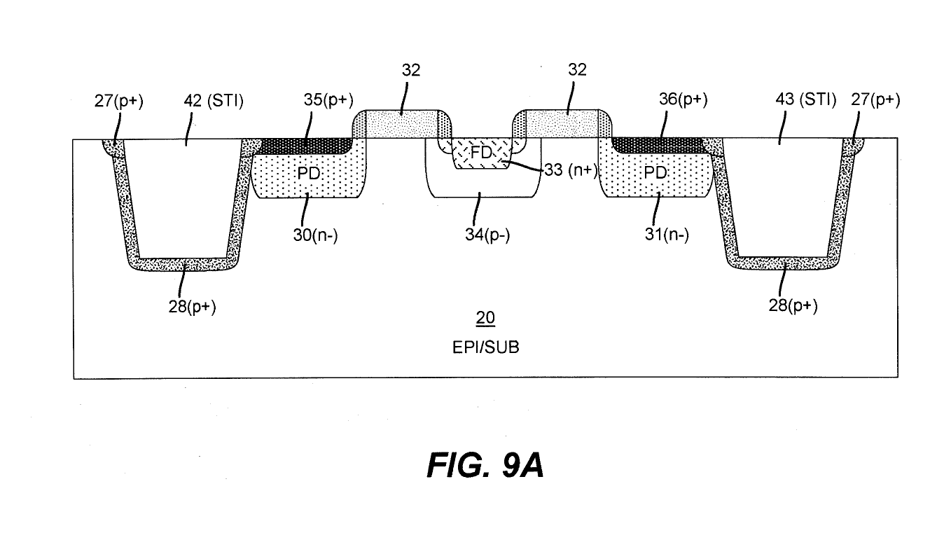

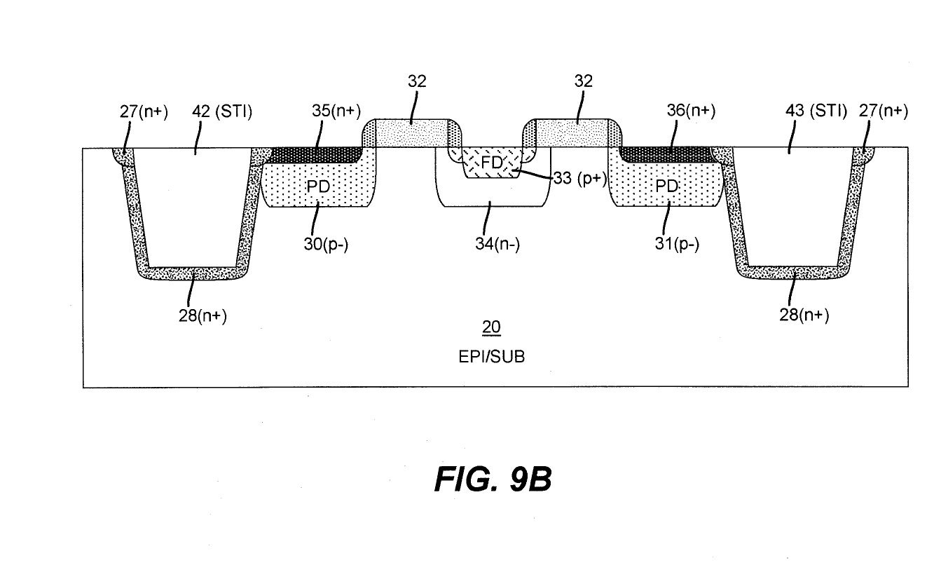

Referring to FIG. 9a, a first cross-sectional view of a semiconductor substrate containing devices between two shallow trench isolations with sidewall implants in embodiments in accordance with the invention is shown. STI regions 42, 43 are shown adjacent to photodetectors 30, 31, respectively. Photodetectors 30, 31 have a conductivity type that is opposite the conductivity type of implant dopant 28 and corner implants 27. When transfer gate 32 is pulsed, charge is transferred from one photodetector (e.g., photodetector 30) into floating diffusion 33, also referred to as a sensing node, contained in well 34. The signal is then sensed by the pixel amplifier (not shown) and fed into the downstream circuitry (not shown) outside of the pixel array. Floating diffusion 33 has a conductivity type that is opposite the conductivity type of implant dopant 28 and corner implants 27.

FIG. 9b shows a second cross-sectional view of a semiconductor substrate containing devices between two shallow trench isolations with sidewall implants in embodiments in accordance with the invention. The conductivity type of corner implants 27, implant dopant 28, photodetectors 30, 31, floating diffusion 33, well 34, and pining layers 35, 36 is reversed with respect to the conductivity types shown in FIG. 9a.

The first hard mask layer and second hard mask layer have been removed from the structure shown in FIGS. 9a and 9b. However, it is understood that these layers may alternatively remain in the final structure. Although an image sensor with two shared photodetectors is shown in FIGS. 9a and 9b it is understood that any number of photodetectors may be used. Typically one, two or four photodetectors can be connected to a single floating diffusion by transfer gates. The photodetectors are usually formed at a depth that is less than the shallow trench.

### PARTS LIST

| | |
|---|---|
| 10 | semiconductor substrate |
| 11 | oxide film layer |
| 12 | photoresist mask |
| 13 | corner implants |
| 14 | side wall implants |
| 18 | opening in photoresist mask |
| 19 | opening in first hard mask layer |
| 20 | semiconductor substrate |
| 21 | etch-stop layer |
| 22 | first hard mask layer |
| 23 | photoresist mask |
| 24 | shallow implant |
| 25 | second hard mask layer |
| 26 | sidewall spacers |
| 27 | corner implants |
| 28 | implant dopant |
| 29 | dielectric layer |
| 30 | photodetector |
| 31 | photodetector |
| 32 | transfer gate |
| 33 | floating diffusion |
| 34 | well |
| 35 | pining layer |
| 36 | pining layer |
| 40 | shallow trench |
| 42 | shallow trench isolation |
| 43 | shallow trench isolation |

1. A method for forming an isolation region in a semiconductor substrate to isolate devices formed in the substrate, comprising:
forming a shallow implant in a portion of the semiconductor substrate by implanting a first dopant through an opening in a first hard mask layer;
forming a second hard mask layer over the portion of the semiconductor substrate and the first hard mask layer;
etching the second hard mask layer to form sidewall spacers along the sides of the first hard mask layer, wherein each sidewall spacer overlies a portion of the shallow implant in the semiconductor substrate; and
etching into the semiconductor substrate between the sidewall spacers to form an isolation trench.

2. The method of claim 1, further comprising:
forming an etch-stop layer over the semiconductor substrate surface;
forming the first hard mask layer over the etch-stop layer;
providing a photoresist mask layer over the first hard mask layer;
patterning the photoresist mask layer to form an opening in the photoresist mask layer; and
etching the first hard mask layer through the opening in the photoresist mask layer to form the opening in the first hard mask layer.

3. The method of claim 1 further comprising:
implanting a second dopant into the side and bottom walls of the isolation trench.

4. The method of claim 3 further comprising forming a conformal insulating layer over the side and bottom walls of the isolation trench.

5. The method of claim 3 wherein the second dopant has the same conductivity type as the first dopant.

6. The method of claim 2 further comprising the step of forming a photodetector in the semiconductor substrate for capturing light and converting it to a charge, wherein the photodetector is laterally adjacent the isolation trench.

7. The method of claim 2 wherein the step of etching the semiconductor substrate between the sidewall spacers to form an isolation trench self aligns the edge of the first dopant with the side walls of the hard mask layer.

8. A method for forming a shallow trench isolation region in an image sensor substrate to isolate devices formed in the substrate, comprising:
a. forming an etch-stop layer on the semiconductor substrate surface;
b. forming a first hard mask layer over the etch-stop layer, wherein the hard mask layer is comprised of a material that is different from a material in the etch-stop layer;
c. providing a photoresist mask layer over the first hard mask layer;
d. patterning the photoresist mask layer to form an opening in the photoresist layer;
e. etching the first hard mask layer through the opening in the photoresist mask layer to form an opening in the first hard mask layer;
f. implanting a first dopant through the opening in the photoresist mask layer, through the opening in the first hard mask layer, and through the etch-stop layer to form a shallow implant in the semiconductor substrate;
g. removing the photoresist mask layer;
h. forming a second hard mask layer over the structure remaining after step g;
i. etching the second hard mask layer to form sidewall spacers along the sides of the first hard mask layer, wherein each sidewall spacer overlies a portion of the shallow implant in the semiconductor substrate; and
j. etching through the etch-stop layer and into the semiconductor substrate between the sidewall spacers to form an isolation trench.

9. The method of claim 8, further comprising implanting a second dopant having the same conductivity type as the first dopant into the side and bottom walls of the isolation trench.

10. The method of claim 8 wherein said first dopant has a conductivity type that is the same as the conductivity type of the underlying region in the substrate.

11. The method of claim 8 wherein said second hard mask layer is conformal.

12. The method of claim 8 wherein etching the second hard mask layer to form sidewall spacers on the sides of the first hard mask layer comprises anisotropically etching the second hard mask layer to form sidewall spacers on the sides of the first hard mask layer.

13. The method of claim 8 wherein etching through the etch stop layer and into the semiconductor substrate between the sidewall spacers to form an isolation trench comprises anisotropically etching through the etch stop layer and into the semiconductor substrate between the sidewall spacers to form an isolation trench.

14. The method of claim 8 wherein said semiconductor substrate is selected from the group consisting of silicon, silicon-on-insulator, silicon-germanium and gallium-arsenide.

15. The method of claim 8 further comprising the step of forming a conformal insulating layer over the side and bottom walls of the isolation trench prior to implanting the second dopant.

16. The method of claim 8 further comprising the step of forming a conformal insulating layer over the side and bottom walls of the isolation trench after implanting said second dopant.

17. The method of claim 8 further comprising the step of forming a photodetector in the image sensor substrate for capturing light and converting it to a charge.
